(19) United States
(12) Patent Application Publication
(10) Pub. No.: US 2024/0071823 A1
(43) Pub. Date: Feb. 29, 2024

(54) SEMICONDUCTOR DEVICE CIRCUITRY FORMED THROUGH VOLUMETRIC EXPANSION

(71) Applicant: Micron Technology, Inc., Boise, ID (US)

(72) Inventors: Kyle K. Kirby, Eagle, ID (US); Terrence B. McDaniel, Boise, ID (US)

(21) Appl. No.: 18/237,174

(22) Filed: Aug. 23, 2023

Related U.S. Application Data
(60) Provisional application No. 63/401,680, filed on Aug. 28, 2022.

(51) Int. Cl. H01L 21/768; H01L 23/00; H01L 23/48; H01L 23/522; H01L 23/532

(52) U.S. Cl. CPC H01L 21/76882; H01L 21/76898; H01L 23/481; H01L 23/5226; H01L 23/53228; H01L 24/08; H01L 2224/08145

(57) ABSTRACT

A semiconductor assembly is described that includes a semiconductor die having first circuitry. The semiconductor die further includes second circuitry with a reservoir of conductive material and an interlayer dielectric having one or more openings between the first circuitry and the reservoir of conductive material. The reservoir of conductive material is heated effective to cause the reservoir of conductive material to volumetrically expand through the one or more openings to create one or more vias that electrically couples the first circuitry and the reservoir of conductive material. In doing so, a connected semiconductor device may be assembled.

### CROSS-REFERENCE TO RELATED APPLICATION(S)

The present application claims priority to U.S. Provisional Patent Application No. 63/401,680, filed Aug. 28, 2022, the disclosure of which is incorporated herein by reference in its entirety.

### TECHNICAL FIELD

The present disclosure generally relates to semiconductor device assemblies, and more particularly relates to semiconductor device circuitry formed through volumetric expansion.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIGS. 1A and 1B illustrate simplified schematic cross-sectional views of a series of fabrication steps for semiconductor device assemblies.

FIGS. 2A and 2B illustrate simplified schematic cross-sectional views of a series of fabrication steps for semiconductor device assemblies in accordance with an embodiment of the present technology.

FIGS. 3A and 3B illustrate simplified schematic cross-sectional views of a series of fabrication steps for semiconductor device assemblies in accordance with an embodiment of the present technology.

FIGS. 4A and 4B illustrate simplified schematic cross-sectional views of a series of fabrication steps for semiconductor device assemblies in accordance with an embodiment of the present technology.

FIGS. 5A and 5B illustrate simplified schematic cross-sectional views of a series of fabrication steps for semiconductor device assemblies in accordance with an embodiment of the present technology.

FIG. 6 illustrates a simplified schematic cross-sectional view of a semiconductor device assembly in accordance with an embodiment of the present technology.

FIG. 7 illustrates a schematic view showing a system that includes a semiconductor device assembly configured in accordance with an embodiment of the present technology.

FIG. 8 illustrates an example method for fabricating a semiconductor device assembly in accordance with an embodiment of the present technology.

### DETAILED DESCRIPTION

Semiconductor devices are integrated in many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, designers continue to develop new techniques to increase the number of circuit elements on a semiconductor device without increasing the size of the device. This development, however, may not be sustainable due to various challenges that arise from designing semiconductor devices with high circuit density. Thus, additional techniques may be required to continue the growth in capability of semiconductor devices.

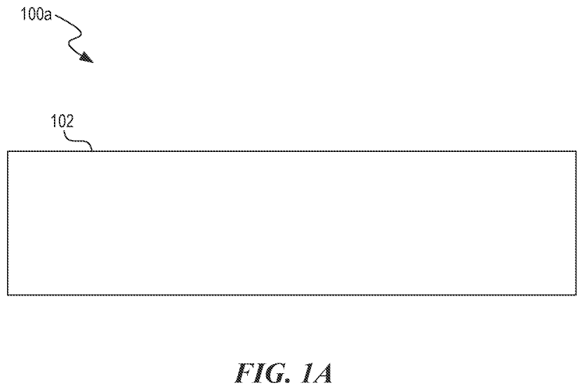

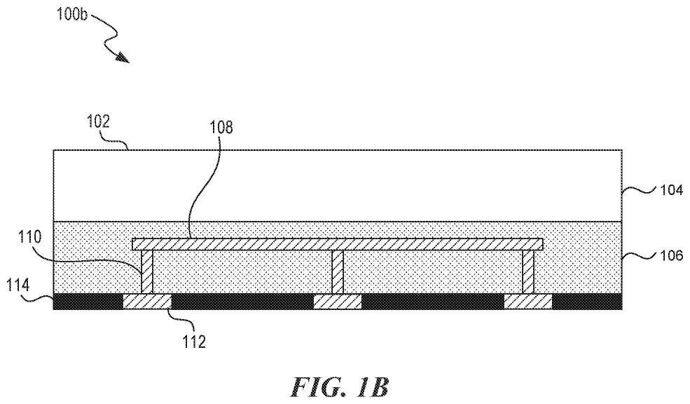

One such technique is to implement multiple semiconductor dies within a single package. These multiple dies may be stacked to increase the number of circuit elements within the package without increasing a footprint (e.g., horizontal area) of the device. Stacked semiconductor devices (e.g., three-dimensional interface (3DI) packaging solutions) are often implemented as a set of multiple semiconductor dies disposed on silicon wafers. Each of the multiple semiconductor dies may include metallization layers that implement circuit components to provide various functionality. Internal and external connective elements are implemented within and between each of the semiconductor dies to enable electrical communication between the various circuit components. Many solutions for connecting semiconductor dies, however, may be suboptimal for producing a reliable, well-connected semiconductor device. One such semiconductor device assembly is illustrated by way of example in FIGS. 1A and 1B.

Beginning with FIG. 1A, a semiconductor device assembly 100a includes a semiconductor die 102. The semiconductor die 102 may include a die substrate, such as a semiconductor wafer or a portion thereof. The die substrate may include any appropriate semiconductor material, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means. The die substrate may provide a surface at which conductive material and dielectric material may be implemented to provide functionality to the semiconductor die. The semiconductor die 102 may be created through a process of depositing and removing layers of material to produce a desired design. In this way, the semiconductor die 102 may be developed in layers until the design is complete. The resulting semiconductor die 102 is shown by way of example in FIG. 1B.

FIG. 1B illustrates an example semiconductor device assembly 100b, which includes the semiconductor die 102. The semiconductor die 102 may include a die substrate 104 and a metallization layer 106. The metallization layer 106 has various circuitry formed from conductive material deposited during the die development process and connected to circuitry in the die substrate 104. For example, routing circuitry (e.g., traces, lines, vias, and other connective elements) may be implemented to connect various circuit components on the semiconductor die 102. As illustrated in FIG. 1B, traces 108 and vias 110 are implemented at the semiconductor die 102. The semiconductor die 102 further includes contact pads 112 exposed at a dielectric layer 114. The dielectric layer 114 may act as a passivized, outermost portion of the semiconductor die 102 that insulates circuitry and connections of the semiconductor die 102. The contact pads 112 may be electrical contacts at which an additional die or a substrate may electrically couple to the semiconductor die 102. The contact pads 112 may couple to vias 110 or traces 108 to provide connectivity between circuitry within the semiconductor die 102 and one or more internal or external circuit components. Thus, the semiconductor die 102 may be connected to provide functionality (e.g., power, grounding, input/output (I/O) signaling, etc.) to the semiconductor die 102.

In contrast to the semiconductor device described with respect to FIGS. 1A and 1B, various embodiments of the present application exploit the thermophysical properties of conductive material, such as copper. When heated, conductive material may expand in volume based on a coefficient of expansion. Given that this expansion is predictable, semiconductor devices may be designed with reservoirs of conductive material located adjacent to vacancies to enable the conductive material to expand into these vacancies and create connective structures that couple the various circuit components in the semiconductor device. In doing so, a robust and well-connected semiconductor device may be assembled through the thermal expansion of conductive material.

For example, a semiconductor assembly is described that includes a semiconductor die having first circuitry. The semiconductor die further includes second circuitry with a reservoir of conductive material and an interlayer dielectric having one or more openings between the first circuitry and the reservoir of conductive material. The reservoir of conductive material is heated effectively to cause the reservoir of conductive material to volumetrically expand through the one or more openings to create one or more vias that electrically couple the first circuitry and the reservoir of conductive material.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die) such as a wafer-level substrate or a die-level substrate, or another die for die-stacking or 3DI applications.

A person having ordinary skill in the relevant art will recognize that suitable steps of the methods described herein can be performed at the wafer level or at the die level. Thus, although some examples may be illustrated or described with respect to dies or wafers, the technology disclosed herein may apply to dies or wafers. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, spin coating, and/or other suitable techniques. Similarly, materials can be removed, for example, using plasma etching, wet etching, chemical-mechanical planarization, or other suitable techniques.

As used herein, the terms “vertical,” “lateral,” “upper,” and “lower” can refer to relative directions or positions of features in the semiconductor die assemblies in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

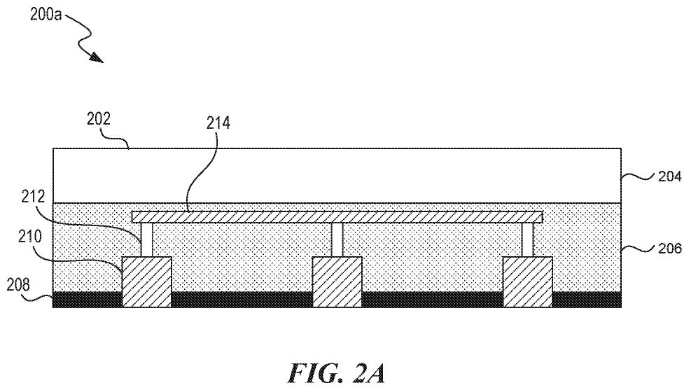

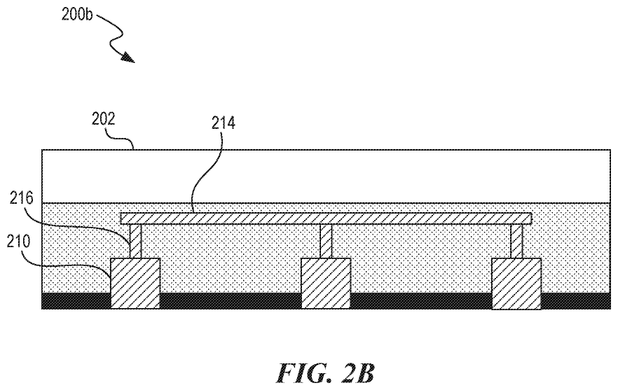

FIGS. 2A and 2B illustrate operations for fabricating a semiconductor device assembly in accordance with an embodiment of the present technology. Beginning with FIG. 2A, a semiconductor device assembly 200a that includes a semiconductor die 202 is illustrated. The semiconductor die 202 includes a die substrate 204, a metallization layer 206, and a dielectric layer 208 that acts as an insulation layer to insulate circuitry and connections at the die 202. The dielectric layer 208 may include a dielectric material, for example, silicon oxide, silicon nitride, silicon carbide, or silicon carbon nitride. The dielectric layer 208 may be created through any appropriate technique, for example, oxidation or deposition. Circuitry or dielectric material may be disposed at the die substrate beneath the dielectric layer 208 (e.g., at the metallization layer 206) to implement traces, lines, vias, transistors, or other circuit elements within the semiconductor die 202. The metallization layer 206 may include layers of conductive material and layers of dielectric material to form the circuitry. For example, layers of circuitry may be separated by interlayer dielectric material. The circuitry may be disposed between the interlayer dielectric and the die substrate 204.

One or more reservoirs of conductive material 210 may be implemented at the semiconductor die 202 (e.g., above or below the circuitry 214). The reservoirs of conductive material 210 may be disposed at the dielectric layer 208 to implement one or more contact pads that may couple the semiconductor die 202 to an additional semiconductor die or to a substrate. Openings 212 may be implemented between the reservoirs of conductive material 210 and circuitry 214 disposed at the semiconductor die 202 (e.g., at an interlayer dielectric). The circuitry 214 may include routing circuitry (e.g., traces, lines, vias, etc.) or functional circuitry (e.g., transistors, diodes, etc.). The reservoirs of conductive material 210 may be implemented adjacent to the openings 212. The reservoirs of conductive material 210 may include discrete reservoirs of conductive material each corresponding to respective openings of the openings 212 or a single reservoir of conductive material 210 corresponding to the openings 212. Although illustrated as beneath the openings 212, the reservoirs of conductive material 210 may be located at least partially within the openings 212 (e.g., recessed from a distal end of the openings 212). The openings 212 may provide vacancies for the reservoirs of conductive material 210 to expand into. Each of the openings 212 may have a width that is thick enough to implement a connective element at the openings 212. For example, an opening designed for a power interconnect may be thicker than an opening designed for an I/O interconnect.

The openings 212 may be created through any number of appropriate methods. For example, dielectric material and conductive material may only be deposited around the openings 212. Alternatively, the dielectric material or conductive material may be deposited equally across the semiconductor die, and the openings 212 may be etched into the semiconductor die 202. The reservoir of conductive material 210 may be designed with a thickness that enables the reservoir of conductive material 210 to volumetrically expand through the openings 212 and contact the circuitry 214 based on the size of the openings 212, the size of the reservoirs of conductive material 210, and a thermal expansion coefficient of the conductive material (e.g., the reservoir of conductive material 210 is thicker than a contact pad that is not expanded to create circuitry). As non-limiting examples, the thickness may be between 5 and 10 microns. The volume of the reservoirs of conductive material 210 may similarly be sufficiently large to enable the conductive material to expand through the openings 212. For example, the volume of the reservoir of conductive material 210 may be larger than the volume of the openings 212 (e.g., at least five times larger, at least 10 times larger, at least 100 times larger, etc.).

The reservoirs of conductive material 210 may be expanded through an annealing process, which may include any number of operations. For example, a vacuum condition may be created around the semiconductor die 202. An inert gas may be applied to the semiconductor die 202. The reservoirs of the conductive material 210 may be heated to alter properties of the conductive material. For example, the reservoirs of conductive material 210 may expand through the openings 212 to create internal circuitry. Given that the reservoirs of conductive material 210 may have a width larger than the width of the openings 212, the conductive material may expand in multiple dimensions. For example, portions of the conductive material below the openings 212 expand vertically through the openings 212, and portions of the conductive material that are not directly below the openings 212 expand laterally and move more material through the openings 212. The resulting semiconductor device assembly is illustrated by way of example in FIG. 2B.

FIG. 2B illustrates an example semiconductor device assembly 200b that includes the semiconductor die 202. The reservoirs of conductive material 210 may expand through the openings 212 to form connective circuitry 216 electrically coupling the reservoirs of conductive material 210 and the circuitry 214. As a non-limiting example, the connective circuitry 216 may include vias that couple to one or more traces included in the circuitry 214. The reservoirs of conductive material 210 may extend seamlessly through the one or more openings 212 and bond to the circuitry 214 with one or more corresponding metal-metal bonds. In this way, a seam may be present where the connective circuitry 216 and the circuitry 214 bond. The circuitry 214 at the semiconductor die 202 may couple to one or more circuit components coupled to the reservoirs of conductive material 210. The vias may be separated by the interlayer dielectric to form separate circuit components. In implementations where multiple discrete reservoirs of conductive material are implemented, the vias may be independent vias formed from the discrete reservoirs of conductive material.

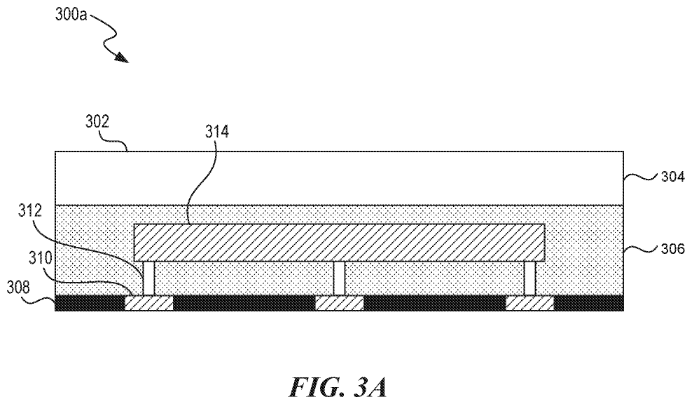

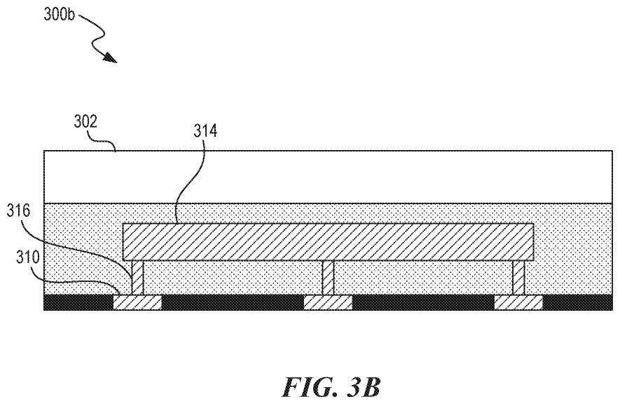

FIGS. 3A and 3B illustrate operations for fabricating a semiconductor device assembly in accordance with an embodiment of the present technology. As illustrated with reference to FIG. 3A, a semiconductor device assembly 300a includes a semiconductor die 302. The semiconductor die 302 includes a die substrate 304 with circuitry thereon, a metallization layer 306 at which metal structures connect to the circuitry at the die substrate 304, and a dielectric layer 308 at which one or more contact pads 310 are disposed. The one or more contact pads 310 may enable the semiconductor die 302 to couple to an additional semiconductor die or to a substrate. The semiconductor die 302 includes one or more openings 312 between the contact pads 310 and a reservoir of conductive material 314 disposed at the semiconductor die 302. The one or more openings 312 may provide a vacancy into which the reservoir of conductive material 314 expands to create circuitry that couples the semiconductor die to any circuit components coupled to the contact pads 310. The reservoir of conductive material 314 may implement one or more circuit components within the semiconductor die 302. For example, the reservoir of conductive material 314 may include one or more traces. The traces may include a quantity of conductive material that enables the conductive material to expand through the openings 312. For example, the traces may be thicker or wider than a trace that is not expanded through the openings 312 (e.g., two, three, four, five times as thick or as wide).

Although illustrated between the contact pads 310 and the traces in the reservoir of conductive material 314, the openings 312 may extend between multiple routing layers of the semiconductor die 302. For example, the openings may extend between a first trace that is implemented within the reservoir of conductive material 314 and an additional trace within the semiconductor die 302. In this way, volumetric expansion may not be constrained to creating circuitry between a contact pad at a dielectric layer and circuitry at a routing layer, but also may create circuitry between various portions of the routing layer. The annealing process may be performed to expand the reservoir of conductive material 314 through the openings 312. The resulting semiconductor device assembly is illustrated by way of example in FIG. 3B.

FIG. 3B illustrates an example semiconductor device assembly 300b that includes the semiconductor die 302. The semiconductor die 302 includes contact pads 310 electrically coupled to the reservoir of conductive material 314 through the circuitry 316. The circuitry 316 may extend from the reservoir of conductive material 314 to the contact pads 310. A metal-metal bond may be formed between the circuitry 316 and the contact pads 310. In this way, a seam may extend between the circuitry 316 and the contact pads 310. The circuitry 316 may include one or more vias that couple traces at the reservoir of conductive material 314 to the contact pads 310. Thus, electrical signaling may be transmitted from the circuitry at the semiconductor die 302 to any circuit component coupled to the contact pads 310 and vice versa.

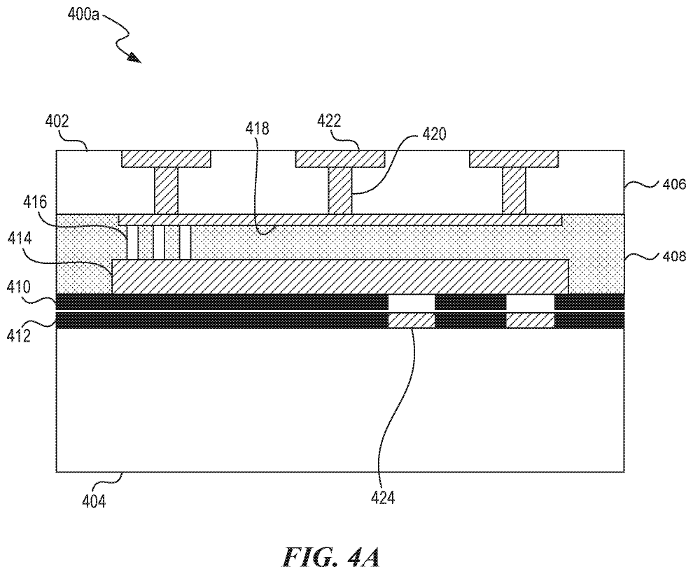

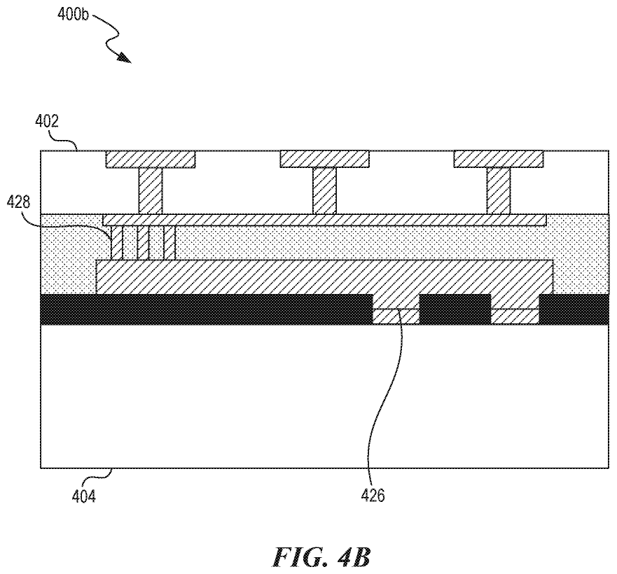

FIGS. 4A and 4B illustrate operations for fabricating a semiconductor device assembly in accordance with an embodiment of the present technology. As illustrated with reference to FIG. 4A, a semiconductor device assembly 400a includes a semiconductor die 402 and a semiconductor die 404. The semiconductor die 402 includes a die substrate 406, a metallization layer 408, a dielectric layer 410, and a reservoir of conductive material 414 disposed at the dielectric layer 410. The semiconductor die 402 further includes circuitry, including traces 418, through-silicon vias (TSV) 420, and contact pads 422 disposed at the semiconductor die 402. The traces 418 may connect to the TSVs 420 that couple to contact pads 422 exposed at a surface of the semiconductor die 402 to enable external connections to additional dies or to a printed circuit board (PCB). Openings 416 extend from the reservoir of conductive material 414 to the circuitry disposed at the semiconductor die 402 to provide vacancies for the conductive material to expand into. In doing so, the conductive material may couple the reservoir of conductive material 414 to the circuitry disposed at the semiconductor die 402 or to additional circuit components coupled to the contact pads 422.

In aspects, the reservoir of conductive material 414 may implement one or more contact pads to enable the semiconductor die 402 to couple to the semiconductor die 404. In aspects, the reservoir of conductive material 414 may be exposed at an exterior of the semiconductor die 402 (e.g., through openings in the dielectric layer 410). The reservoir of conductive material 414 may correspond to contact pads 424 at a dielectric layer 412 of the semiconductor die 404. When the reservoir of conductive material 414 is heated, the conductive material may expand through the openings in the dielectric layer 410 to form interconnects that couple the semiconductor dies at the contact pads 424. Similarly, the conductive material 414 may expand into the openings 416 when heated. In doing so, circuitry within the semiconductor die 402 may electrically couple to the semiconductor die 404. The resulting semiconductor device assembly is illustrated by way of example in FIG. 4B.

FIG. 4B illustrates an example semiconductor device assembly 400b that includes the semiconductor die 402 mounted to the semiconductor die 404. The semiconductor die 402 and the semiconductor die 404 electrically couple through interconnects 426 formed from the reservoir of conductive material 414. The reservoir of conductive material 414 may similarly extend into the openings 416 to create circuitry 428 that couples the circuitry at the semiconductor die 402 to the semiconductor die 404 through the reservoir of conductive material 414 and the interconnects 426. Once the interconnects 426 and the circuitry 428 are formed, electrical signals may pass from the semiconductor die 404 to the semiconductor die 402 or any circuitry thereof. Similarly, electrical signals may be transmitted from the semiconductor die 402 to the semiconductor die 404.

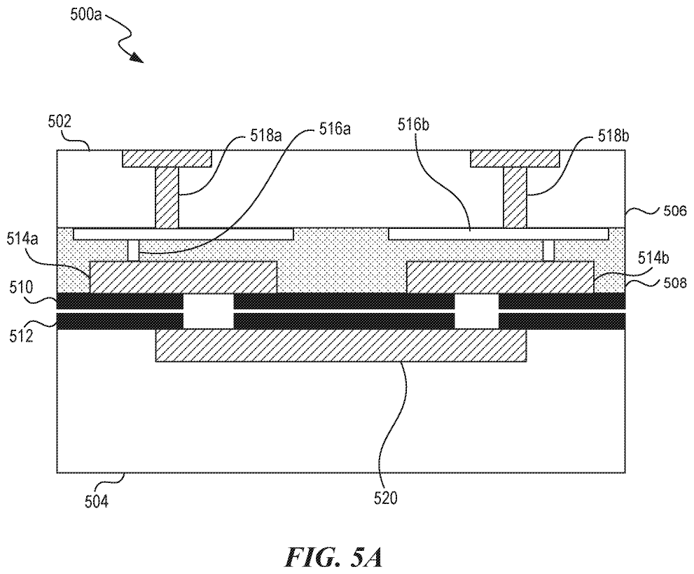

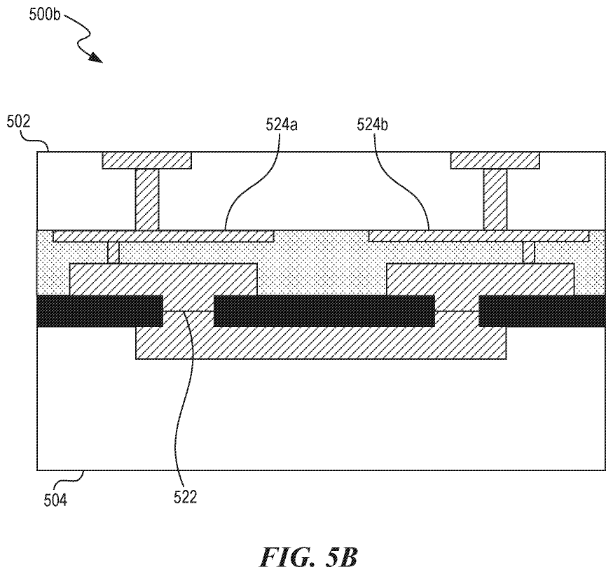

FIGS. 5A and 5B illustrate operations for fabricating a semiconductor device assembly in accordance with an embodiment of the present technology. As illustrated with reference to FIG. 5A, a semiconductor device assembly 500a includes a semiconductor die 502 and a semiconductor die 504. The semiconductor die 502 includes a die substrate 506, a metallization layer 508, a dielectric layer 510, a discrete reservoir of conductive material 514a, a discrete reservoir of conductive material 514b, and various circuitry 518 disposed at the semiconductor die 502. Respective openings 516 may extend between the circuitry 518 and the reservoirs of conductive material 514 to provide vacancies for the reservoirs of conductive material 514 to expand into. For example, an opening 516a may be implemented between a reservoir of conductive material 514a and circuitry 518a, and an opening 516b may be implemented between a reservoir of conductive material 514b and circuitry 518b.

In contrast to the openings illustrated in FIGS. 2A through 4A, the openings 516 may include lateral openings to enable traces to be formed from the reservoirs of conductive material 514. The openings 516 may additionally include vertical openings to enable vias to be formed from the reservoirs of conductive material 514. The reservoirs of conductive material 514 may be volumetrically expanded to electrically couple the circuitry 518 and the reservoirs of conductive material 514. Moreover, the semiconductor die 504 may include a reservoir of conductive material 520 at a dielectric layer 512. The reservoir of conductive material 520 and the reservoirs of conductive material 514 may expand to form interconnects between the semiconductor dies.

The reservoir of conductive material 520 may act as an electrical connection between the discrete reservoir of conductive material 514a and the discrete reservoir of conductive material 514b when the semiconductor die 502 and the semiconductor die 504 are electrically coupled. For example, electrical signals may pass between the reservoir of conductive material 514a and the reservoir of conductive material 514b through the conductive material 520. In some implementations, the reservoir of conductive material 520 may be a lone connection between the reservoir of conductive material 514a and the reservoir of conductive material 514b. For example, the reservoir of conductive material 514a and the reservoir of conductive material 514b may expand through the openings 516a and the openings 516b, respectively, to create discrete circuitry. In other implementations, the reservoirs of conductive material 514 may expand through the openings 516 to create circuitry that couples the reservoir of conductive material 514a and the reservoir of conductive material 514b through circuitry internal to the semiconductor die 502. An example of a semiconductor device assembly after expansion of the reservoir of conductive material 514 is illustrated in FIG. 5B.

FIG. 5B illustrates an example semiconductor device assembly 500b that includes the semiconductor die 502 mounted to the semiconductor die 504. The semiconductor die 502 and the semiconductor die 504 electrically couple through interconnects 522 formed from reservoirs of conductive material. Similarly, circuitry 524a and circuitry 524b are formed from expansion of the reservoirs of conductive material 514a and the reservoirs of conductive material 514b, respectively. In implementations when the circuitry 524a does not couple to circuitry 524b through the semiconductor die 502, the interconnects 522 may couple the reservoir of conductive material 520 to the reservoir of conductive material 514a and the reservoir of conductive material 514b, and thus, electrical signals may be carried between the reservoir of conductive material 514a and the reservoir of conductive material 514b through the reservoir of conductive material 520.

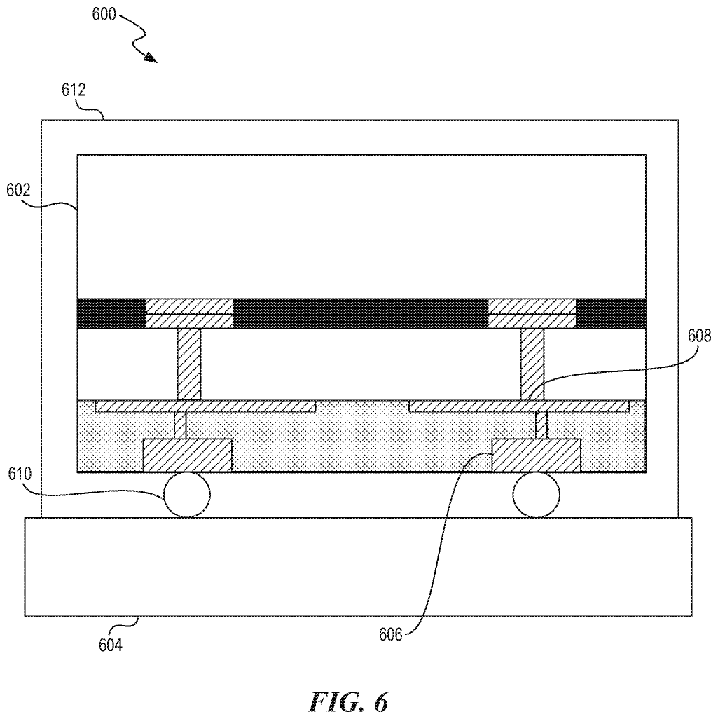

FIG. 6 illustrates a simplified schematic cross-sectional view of a semiconductor device assembly 600 in accordance with an embodiment of the present technology. The semiconductor device assembly 600 includes stacked semiconductor dies 602 assembled onto a substrate 604. The substrate 604 may include a PCB, an interposer, or one or more additional dies. The stacked semiconductor dies 602 may electrically and mechanically couple through interconnects (e.g., solder balls, copper pillars, etc.). In some implementations, the stacked semiconductor dies 602 may electrically couple (e.g., and mechanically couple) through interconnects that are formed by annealing one or more reservoirs of conductive material to volumetrically expand the conductive material through openings in the dielectric layers. The interconnects couple to circuitry 608 disposed at a base die of the stacked semiconductor device. The circuitry 608 may include TSVs that couple to traces and other circuitry within a base die of the stacked semiconductor dies 602. The traces may couple to reservoirs of conductive material 606 that implement contact pads through vias to provide external connectivity to the stacked semiconductor dies 602.

Any of the circuitry 608 may be formed through volumetric expansion of the reservoirs of conductive material 606. For example, any of the vias or traces may be formed by heating the reservoirs of conductive material 606 to cause the conductive material to volumetrically expand into openings in the semiconductor die. Connective structures 610 (e.g., solder balls, copper pillars, etc.) couple the reservoirs of conductive material 606 to contact pads implemented at the substrate 604. The contact pads at the substrate 604 may couple to various routing circuitry that provides connectivity to one or more internal or external circuit components to provide functionality to the stacked semiconductor dies 602. In some implementations, the stacked semiconductor dies 602 may be at least partially encapsulated by an encapsulant 612 to protect them from environmental factors (e.g., moisture, particulates, static electricity, and physical impact).

Although in the foregoing example embodiment semiconductor device assemblies have been illustrated and described as including a particular number of semiconductor dies, in other embodiments assemblies can be provided with more or less semiconductor dies. For example, the two-die semiconductor devices illustrated in FIGS. 4 through 6 could be replaced with, for example, a vertical stack of semiconductor devices, a plurality of semiconductor devices, mutatis mutandis.

In accordance with one aspect of the present disclosure, the semiconductor devices illustrated in the assemblies of FIGS. 2-6 could be memory dies, such as dynamic random-access memory (DRAM) dies, NOT-AND (NAND) memory dies, NOT-OR (NOR) memory dies, magnetic random-access memory (MRAM) dies, phase change memory (PCM) dies, ferroelectric random-access memory (FeRAM) dies, static random-access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

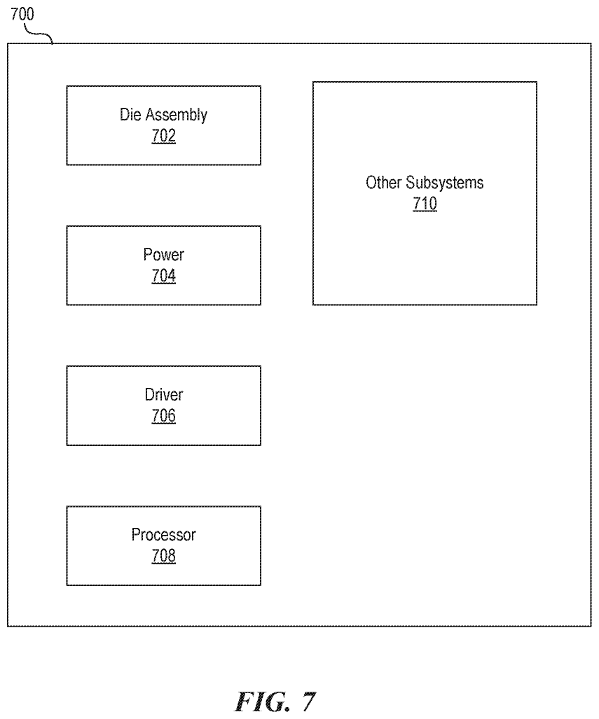

Any one of the semiconductor devices and semiconductor device assemblies described above with reference to FIGS. 2 through 6 can be incorporated into any of a myriad of larger and/or more complex systems, a representative example of which is system 700 shown schematically in FIG. 7. The system 700 can include a semiconductor device assembly 702 (e.g., or a discrete semiconductor device), a power source 704, a driver 706, a processor 708, and/or other subsystems or components 710. The semiconductor device assembly 702 can include features generally similar to those of the semiconductor devices described above with reference to FIGS. 2 through 6. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, vehicles, appliances, and other products. Components of the system 700 may be housed in a single unit or distributed over multiple, interconnected units (e.g., through a communications network). The components of the system 700 can also include remote devices and any of a wide variety of computer-readable media.

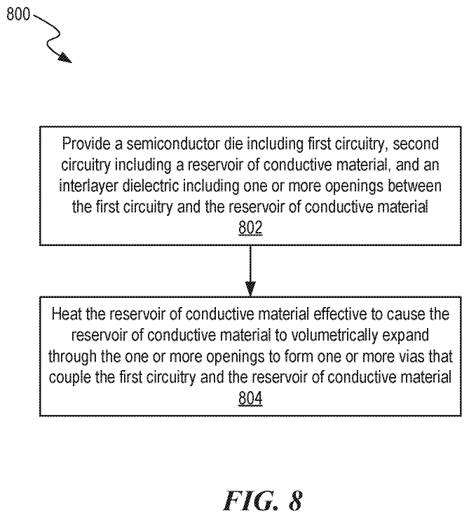

FIG. 8 illustrates an example method 800 for fabricating a semiconductor device assembly in accordance with an embodiment of the present technology. The method 800 may, for illustrative purposes, be described by way of example with respect to features, components, or elements of FIGS. 2 through 7. Although illustrated in a particular configuration, one or more operations of the method 800 may be omitted, repeated, or reorganized. Additionally, the method 800 may include other operations not illustrated in FIG. 8, for example, operations detailed in one or more other method described herein.

At 802, a semiconductor die 202 is provided. The semiconductor die 202 includes a first circuitry 214 disposed at the semiconductor die 202 and a second circuitry including a reservoir of conductive material 210. An interlayer dielectric having one or more openings 212 between the first circuitry 214 and the reservoir of conductive material 210 may be implemented. In aspects, the first circuitry 214 may include one or more traces, vias, contact pads or other connective elements. The second circuitry may similarly include one or more traces, vias, contact pads, or other connective elements.

At 804, the reservoir of conductive material 210 may be heated. The heating may cause the reservoir of conductive material 210 to volumetrically expand (e.g., vertically and laterally) through the one or more openings 212 to form one or more vias in the one or more openings 212 that electrically couple the first circuitry 214 and the reservoir of conductive material 210. In some implementations, the reservoir of conductive material may include a plurality of discrete reservoirs of conductive material, and the one or more vias may be independent vias separated by the interlayer dielectric and formed from respective reservoirs of conductive material. Thus, volumetric expansion of conductive material may be utilized to create circuitry internal to a semiconductor die and fabricate a robust and well-connected semiconductor device.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C, or AB or AC or BC, or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A method of making a semiconductor device assembly, comprising:
providing a semiconductor die including:
first circuitry;
second circuitry including a reservoir of conductive material; and
an interlayer dielectric including one or more openings between the first circuitry and the reservoir of conductive material; and
heating the reservoir of conductive material effectively to cause the reservoir of conductive material to volumetrically expand through the one or more openings to form one or more vias in the one or more openings that electrically couple the first circuitry and the reservoir of conductive material.

2. The method of claim 1, wherein:
the first circuitry comprises one or more traces;
the second circuitry further comprises one or more contact pads configured to couple the semiconductor die and an additional semiconductor die; and
the one or more vias couple the one or more contact pads and the one or more traces.

3. The method of claim 1, wherein the first circuitry is above the second circuitry.

4. The method of claim 1, wherein the first circuitry comprises one or more through-silicon vias extending through the semiconductor die.

5. The method of claim 1, wherein:
the reservoir of conductive material comprises multiple discrete reservoirs of conductive material; and
the one or more vias comprise a plurality of vias, each of the plurality of vias separated by the interlayer dielectric and formed from a respective one of the multiple discrete reservoirs.

6. The method of claim 1, wherein a volume of the reservoir of conductive material is at least 10 times a volume of the openings.

7. A semiconductor device assembly, comprising:
a semiconductor die including:
first circuitry;
second circuitry including a reservoir of conductive material; and
an interlayer dielectric including one or more openings between the first circuitry and the reservoir of conductive material,
one or more vias electrically extending through the one or more openings and coupling the first circuitry and the reservoir of conductive material, the one or more vias extending seamlessly from the reservoir and bonded to the first circuitry with one or more corresponding metal-metal bonds.

8. The semiconductor device assembly of claim 7, wherein the first circuitry is disposed between the interlayer dielectric and a semiconductor substrate of the semiconductor die.

9. The semiconductor device assembly of claim 7, wherein the first circuitry comprises one or more traces.

10. The semiconductor device assembly of claim 7, wherein the conductive material includes copper.

11. The semiconductor device assembly of claim 7, wherein the reservoir of conductive material has a first width that is greater than a second width of the one or more openings.

12. The semiconductor device assembly of claim 7, wherein the reservoir of conductive material has a thickness between 5 and 10 microns.

13. The semiconductor device assembly of claim 7, wherein the second circuitry includes one or more traces.

14. The semiconductor device assembly of claim 7, wherein the first circuitry comprises one or more contact pads configured to couple to an additional semiconductor die.

15. A semiconductor die, wherein the semiconductor die is fabricated by:
providing first circuitry at the semiconductor die;
providing second circuitry including a reservoir of conductive material at the semiconductor die;
providing an interlayer dielectric including one or more openings between the first circuitry and the reservoir of conductive material; and
heating the reservoir of conductive material effective to cause the reservoir of conductive material to volumetrically expand through the one or more openings to form one or more vias that electrically couple the first circuitry and the reservoir of conductive material.

16. The semiconductor die claim 15, wherein:
the first circuitry comprises one or more traces;
the second circuitry further comprises one or more contact pads configured to couple the semiconductor die and an additional semiconductor die; and
the one or more vias couple the one or more contact pads and the one or more traces.

17. The semiconductor die of claim 15, wherein the conductive material comprises copper.

18. The semiconductor die of claim 15, wherein:
the first circuitry comprises one or more traces;
the second circuitry comprises one or more additional traces; and
the one or more vias couple the one or more traces and the one or more additional traces.

19. The semiconductor die of claim 15, wherein the first circuitry comprises one or more through-silicon vias extending through the semiconductor die.

20. The semiconductor die of claim 15, wherein a volume of the reservoir of conductive material is at least 10 times a volume of the openings.
